(19) United States
(12) Patent Application Publication
(10) Pub. No.: US 2006/0022670 A1
(43) Pub. Date: Feb. 2, 2006

(54) Magnetic resonance screening portal with combination sensing

(75) Inventors: Sankaran Kumar, San Marcos, CA (US); Peter V. Czipott, San Diego, CA (US); Richard J. McClure, San Diego, CA (US)

Correspondence Address: GERALD W. SPINKS, P. O. BOX 5242, GLACIER, WA, 98244, US

(73) Assignees: MedNovus, Inc., Leucadia, CA (US); Quantum Magnetics, Inc., San Diego, CA (US)

(21) Appl. No.: 11/031,332

(22) Filed: Jan. 5, 2005

Related U.S. Application Data
(60) Provisional application No. 60/592,928, filed on Jul. 31, 2004.

(51) Int. Cl. G01N 27/72; G01R 33/12; G01V 3/00

(52) U.S. Cl. 324/239

(57) ABSTRACT

A screening portal for detecting the passage of ferromagnetic threat objects, whether permanently magnetized or not, by the use of AC induction coil sensors to detect a non-magnetized object, in combination with sensors capable of detecting the passage of a permanently magnetized object.

### CROSS REFERENCE TO RELATED APPLICATIONS

This application claims the benefit of U.S. Provisional Pat. App. No. 60/592,928, filed on Jul. 31, 2004, and entitled “Magnetic Resonance Screening Portal with Combination Sensing.”

### STATEMENT REGARDING FEDERALLY SPONSORED RESEARCH OR DEVELOPMENT

Not Applicable

### BACKGROUND OF THE INVENTION

1. Field of the Invention

This invention is in the field of screening devices for preventing ferromagnetic or magnetic metal objects from being in the vicinity of an operating magnetic resonance imaging apparatus.

2. Background Art

Magnetic resonance imaging (MRI) has been called “the most important development in medical diagnosis since the discovery of the x-ray” 100 years ago. Magnetic resonance imaging has significant risks, however, and these are becoming more apparent as the number of MRI procedures increases dramatically. In particular, ferromagnetic objects are drawn toward the magnetic resonance imaging magnet by the strong magnetic field of the magnet, sometimes with catastrophic results. This attraction of ferromagnetic objects to the MRI magnet is termed the “missile threat.” Not only have there been numerous injuries to patients, including one tragic death, but damage to the MRI magnet itself is also a significant problem.

In an effort to provide safety, MRI centers have attempted to utilize conventional metal detectors, such as those used for airport and other security applications. Conventional metal detectors alarm not only on ferromagnetic threat objects, but also on non-threat, non-ferromagnetic, metallic objects. The huge number of false positive alarms generated by conventional metal detectors has caused such consternation for MRI staff technicians that conventional metal detectors have been abandoned for this application. Indeed, conventional metal detectors may have no current usefulness as a practical solution for MRI safety.

Magnifying the threat potential for serious harm is the next generation of MRI magnets, which are even more powerful than current generations, generating magnetic fields of 3.0 Tesla, or 30,000 Gauss, as opposed to today's “standard” of 1.5 Tesla, or 15,000 Gauss. A ferromagnetic object, such as a small pipe wrench, can be drawn in instantaneous missile-like fashion toward the MRI magnet. The force of the magnetic attraction between the pipe wrench and the MRI magnet causes the wrench to fly toward the magnet as if propelled by a rocket.

### BRIEF SUMMARY OF THE INVENTION

Unlike conventional metal detectors, which alarm on metals regardless of the presence or absence of ferromagnetic qualities, the present invention uses sensor technology which is specific for detecting only ferromagnetic materials. As alarms are limited to materials which are potentially dangerous in a magnetic resonance imaging setting, the problem of false positives seen with conventional metal detectors is absent.

The present invention provides a walk-through/pass-through portal system which detects ferromagnetic threat objects which could pose a safety hazard in the proximity of the magnetic resonance imaging magnet. The invention is a fail-safe portal system which alarms on ferromagnetic threats, and, in the preferred embodiment, automatically restricts access to the magnet room of an MRI center whenever a patient or staff member has upon his or her person a potentially harmful ferromagnetic threat object. When a threat is detected, audio and visual alarms are activated. The portal can be stand-alone, or, alternatively, it can be built into the MRI center's architecture. Patients and other personnel can either walk through the portal, or pass through upon a non-ferromagnetic gurney or in a non-ferromagnetic wheelchair.

Although the vast majority of ferromagnetic threat objects are not permanent magnets, it is nevertheless essential that significant ferromagnetic threats be detected, including the small number which are permanent magnets. In the world of medicine, every possible step must be taken to ensure the greatest sensitivity and reliability, and the present invention is aimed at this goal.

Therefore, the present invention utilizes a combination of a plurality of relatively small AC induction coil sensors, along with one or more other sensors which are particularly suited to detect a permanent magnet threat object, that is, a threat object which is made of a saturated permeable material, or a material close to saturation. The sensor or sensors which are particularly suited to detect permanent magnets can be either a large induction coil sensor or one or more DC type sensors. Use of DC sensors is generally preferred, since large induction coil sensors, in order to be adequate detectors of saturated, or close to saturated, permeable materials, are quite sizable.

The novel features of this invention, as well as the invention itself, will be best understood from the attached drawings, taken along with the following description, in which similar reference characters refer to similar parts, and in which:

### BRIEF DESCRIPTION OF THE SEVERAL VIEWS OF THE DRAWINGS

FIG. 1 is a schematic view of a first embodiment of the portal according to the present invention, with a combination of small AC induction coil sensors and DC type sensors;

FIG. 2 is a schematic view of a second embodiment of the portal according to the present invention, with a combination of small AC induction coil sensors and a large induction coil sensor; and

FIG. 3 is a graph of a hysteresis curve, illustrating the difficulty of detecting both permanently magnetized and non-magnetized threat objects with a single type of sensor.

### DETAILED DESCRIPTION OF THE INVENTION

Throughout this application, the term “DC sensor,” or “DC type sensor,” means a sensor, or a configuration of sensors such as a gradiometer, which detects the presence of a static or slowly varying magnetic field emanating from a permanent magnet threat object. Further, the term “AC induction coil sensor” means an induction coil sensor, or a configuration of sensors, which senses the response of magnetically permeable objects to the application of an AC magnetic field. The term “large induction coil sensor” refers to a sensor composed of a large induction coil which detects a slowly varying magnetic field, thus sensing the movement of a permanent magnet.

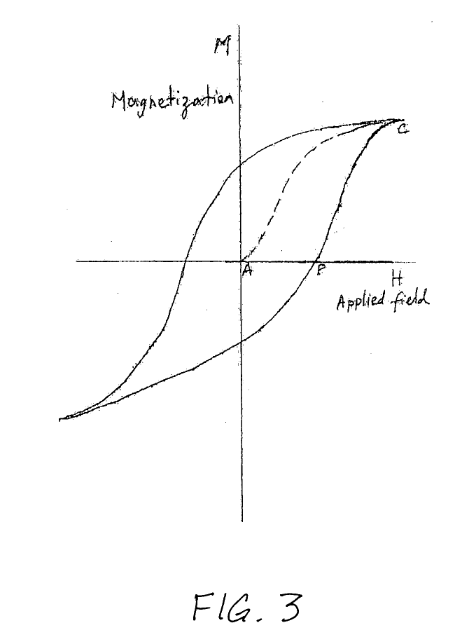

AC magnetic susceptibility can be used to detect the presence of permeable material since the magnetization of the permeable material changes as the applied AC field changes. The relation between the applied AC magnetic field and the magnetization of the material is given by the slope of the material's characteristic M-H, or hysteresis, curve. The response of the permeable material is proportional to the slope of the M-H curve and this slope is a function of the level of magnetization of the material. As illustrated in FIG. 3, at low magnetization, the slope is usually large, as at points A and P. When a ferromagnetic object is in a magnetically saturated condition near either end of a hysteresis curve, the magnetization change caused by an imposed AC magnetic field is very small, rendering detection difficult with AC sensors. On the other hand, when the object is magnetically saturated, a DC type sensor, such as a magneto-resistive sensor, can detect it more readily than can an AC sensor. At higher magnetization, the slope decreases eventually tending to zero, as at point C, since the permeable material is magnetically saturated and cannot be magnetized further, even if the applied magnetic field is increased. Therefore, while the response of a permeable material can be large if its magnetization is low, it can be much smaller if it is magnetized close to saturation. Hence, a permeable material magnetized close to saturation may not give a measurable response to an applied magnetic field.

This fact can be a disadvantage in a detector that attempts to detect objects made of permeable material by using the response to an applied magnetic field. If a detector is designed only to measure the response of the material to an applied AC field, for instance, and the frequency of the applied field is kept sufficiently low so as not to excite significant eddy currents in the material, as is desirable in detectors that one wishes to remain “blind” to conductive but non-permeable metal, the detector may not detect the presence of an object made with a permeable material that is close to saturation. In this case, however, the saturated permeable material may be detected by adding a second detector that can detect static magnetic fields, or a slowly varying magnetic field. Since saturated permeable materials produce significant static magnetic fields, their presence can be readily detected by the second detector even though the first detector, which measures only the AC response, fails to detect the object.

In particular, if a detector portal uses an AC magnetic field excitation coil and induction coils as sensors, unless the induction coil sensor is very large, it may not detect objects such as refrigerator magnets, magnetized hair pins, and the like. A DC type magnetic sensor that is capable of detecting static or slowly varying magnetic fields, e.g. a magneto-resistive, Hall, magneto-inductive, or fluxgate sensor, etc., could detect these magnetized objects. If necessary, more than one DC type sensor can be used and the multiple sensors can be placed at different locations on the portal to enhance detection and get some spatial location information of the object.

The advantage of AC induction coil sensors is greater sensitivity with lower noise. The disadvantage of AC induction coil sensors is that objects which are in and of themselves permanent magnets are not readily detected, unless the AC induction coil sensor is very large. Large induction coils, at very low frequencies, can be configured, however, to detect the changing magnetic field of a permanent magnet passing through the portal. To ensure that threat objects which are permanent magnets are identified, the present invention utilizes either a large induction coil sensor or one or more DC type sensors, with the preferred embodiment of DC type sensors being magneto-resistive sensors. The DC type sensors need not be large, and they are therefore superior to large induction coils, in some applications, for detecting objects which are permanent magnets.

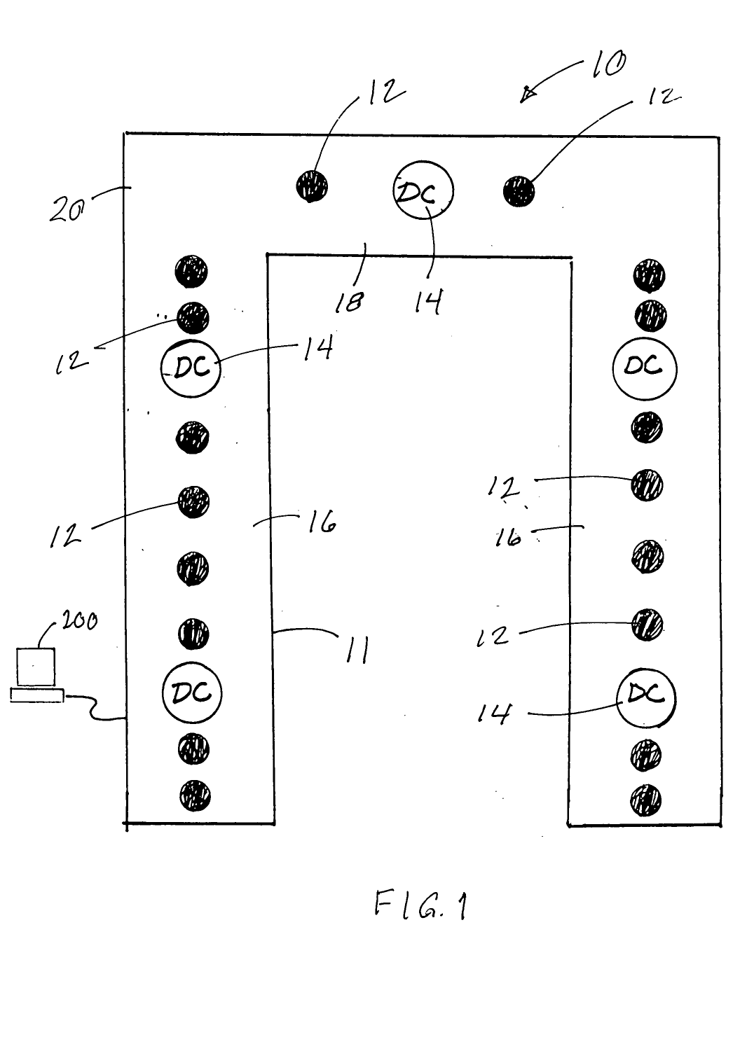

As shown in FIG. 1, a first embodiment of the present invention is a sensor portal 10, with an opening 11 for passage of the person or equipment being screened. This embodiment of the invention uses the combination of an array of small AC induction coil sensors 12, represented by the shaded circles, with one or more DC type sensors 14, such as magneto-resistive sensors. The DC type sensors 14 are preferably 3 to 5 in number. The DC sensors 14 can appropriately be configured as single axis, dual axis, or multi-axis, and they can use a variety of magnetometer technologies, such as gradiometers.

Alternative sensor combinations for this embodiment, for detecting both magnetizable ferromagnetic threat objects and those which are in and of themselves permanent magnets, include, but are not limited to, the following:
(a) AC induction coil sensors in combination with one or more Hall effect sensors;
(b) AC induction coil sensors in combination with one or more fluxgate sensors;
(c) AC induction coil sensors in combination with one or more fiber optic sensors;
(d) AC induction coil sensors in combination with one or more optically pumped sensors;
(e) AC induction coil sensors in combination with one or more nuclear precession sensors;
(f) AC induction coil sensors in combination with one or more magneto-transistor sensors;
(g) AC induction coil sensors in combination with one or more magneto-diode sensors;
(h) AC induction coil sensors in combination with one or more magneto-optical sensors;
(i) AC induction coil sensors in combination with one or more giant magneto-resistive sensors;
(j) AC induction coil sensors in combination with one or more vibration coil sensors;
(k) AC induction coil sensors in combination with one or more magneto-inductive sensors;
(l) AC induction coil sensors in combination with one or more spin-dependent tunneling (SDT) sensors.

It should be noted that this embodiment of the invention is not limited to those combinations listed. Other types of DC sensors 14 can also be used in combination with the AC induction coil sensors 12. In fact, any DC type sensor or sensor configuration which is capable of detecting a permanent magnet can be used in combination with AC induction coil sensors 12, in the embodiment shown in FIG. 1.

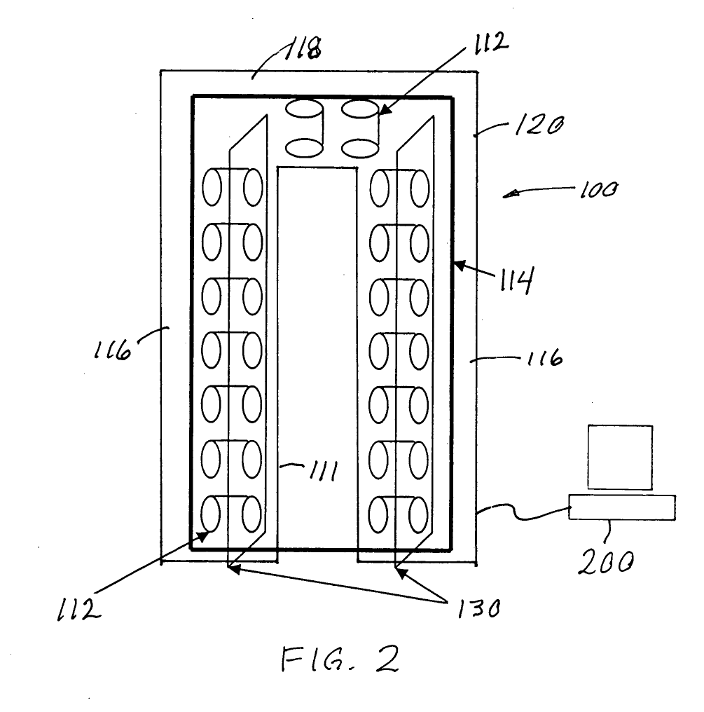

Another embodiment, shown in FIG. 2, is a sensor portal 100 using the combination of an array of small AC induction coil sensors 112 with a large induction coil sensor 114, or sensors, having many turns of wire for sensitivity at a very low frequency, preferably, one Hz or less. The large induction coil sensor is for detecting static or slowly varying magnetic fields. That is, rather than using DC type sensors to detect a permanent magnet, the large induction coil sensor 114 or sensors detect the magnetic field variations which are caused by movement of a permanent magnet threat object as it passes through the opening 111 of the frame 120 of the portal 100.

The present invention, then, in either embodiment, utilizes an array of small AC induction coil sensors, combined with another sensor or sensors which detect permanent magnets. This combination of sensor types thus detects ferromagnetic threat objects, be they unsaturated, partially saturated, or saturated, as in a permanent magnet. The sensors can be configured in the form of gradiometers or other magnetometer technologies, and they can be in single axis, dual axis, or multi-axis configurations. The sensor configurations are appropriately arranged and mounted upon each vertical column 16, 116 of the portal frame 20, 120. Optionally, additional sensors can be positioned across the top horizontal member 18, 118 of the frame 20, 120, to improve detection of threat objects on the head of the patient or other person.

Each sensor 12, 14, 112, 114 measures the presence or absence of a magnetic gradient and produces a signal proportional to this magnetic gradient, when such is present. The output from each sensor 12, 14, 112, 114 or sensor configuration is sent to a computer 200, and computer analyses of the signal from each respective sensor or sensor configuration determine the specific location of the threat object causing the magnetic field distortion. As threat objects can portray different magnetic properties, such as dipoles, quadrupoles, etc., computer analysis is used to determine the location of the threat in question. Threat location is zone specific, and it is feasible to achieve an accuracy of approximately 3 to 6 inches for locating the threat object.

In both of the embodiments, an AC applied magnetic field coil or coil set having one, two, or three orthogonal axes is employed, as this significantly increases the AC induction coil sensor system's sensitivity for detection of those ferromagnetic objects which are magnetizable. One type of such a set of AC applied magnetic field coils 130 is shown in FIG. 2, for exemplary purposes. In this example, the induction coils 112 are configured as gradiometers, and a first applied field coil 130, with a horizontal axis, is positioned on one side 116 of the portal frame 120, bisecting the induction coil gradiometers 112 on that side of the frame 120. Further, a second applied field coil 130 is positioned on the other side 116 of the portal frame 120, bisecting the induction coil gradiometers 112 on that side of the frame 120. Additional applied field coils (not shown) for establishing magnetic fields on the other two axes would be oriented orthogonal to these applied field coils 130, as is known in the art, one having a horizontal axis orthogonal to the horizontal axis of the applied field coils 130, and the other having a vertical axis orthogonal to the horizontal axis of the applied field coils 130. Ferromagnetic threats which are already permanent magnets cannot be further magnetized, as discussed above, and these are detected either by the DC type sensors 14 in FIG. 1 or by the large induction coil 114 in FIG. 2.

While the particular invention as herein shown and disclosed in detail is fully capable of obtaining the objects and providing the advantages hereinbefore stated, it is to be understood that this disclosure is merely illustrative of the presently preferred embodiments of the invention and that no limitations are intended other than as described in the appended claims.

We claim:

1. A portal for detection of ferromagnetic and magnetic threat objects, comprising:
a frame having an opening for passage of a subject to be screened for threat objects;
an applied field coil adapted to establish an AC magnetic field in said opening of said frame;
a plurality of AC induction coils mounted to said frame, said induction coils being adapted to sense an induced magnetic field induced in a threat object by the presence of said applied AC magnetic field;
at least one sensor mounted to said frame, said sensor being adapted to sense a magnetic field established by a permanently magnetized threat object in said opening of said frame.

2. The portal recited in claim 1, wherein said sensor comprises a DC type sensor adapted to sense a static or slowly varying magnetic field established by said permanently magnetized threat object.

3. The portal recited in claim 2, wherein:
at least one said DC type sensor is mounted on a first vertical member of said portal frame on a first side of said opening; and
at least one said DC type sensor is mounted on a second vertical member of said portal frame on a second side of said opening.

4. The portal recited in claim 2, wherein at least one said DC type sensor is mounted on a horizontal member of said frame above said opening.

5. The portal recited in claim 1, wherein said sensor comprises a large induction coil adapted to sense a slowly varying magnetic field established by movement of said permanently magnetized threat object through said opening of said frame.

6. The portal recited in claim 1, wherein:
a first vertical array of said AC induction coils are mounted on a first vertical member of said portal frame on a first side of said opening; and
a second vertical array of said AC induction coils are mounted on a second vertical member of said portal frame on a second side of said opening.

7. The portal recited in claim 6, wherein:
a first said applied field coil is mounted adjacent to said first vertical member of said portal frame;
a second said applied field coil is mounted adjacent to said second vertical member of said portal frame; and
said first and second applied field coils have horizontal axes extending across said opening of said frame.

8. The portal recited in claim 1, wherein a horizontal array of said AC induction coils are mounted on a horizontal member of said frame above said opening.

9. A method for detection of ferromagnetic and magnetic threat objects, comprising:
providing a frame having an opening, at least one applied field coil, and a plurality of AC induction coils;
establishing an AC magnetic field in said opening of said frame with said at least one applied field coil;
passing a subject to be screened for threat objects through said opening;
sensing, with said induction coils, a magnetic field induced in a threat object by the presence of said applied AC magnetic field; and
sensing, with at least one sensor mounted to said frame, a magnetic field established by a permanently magnetized threat object in said opening of said frame.

10. The method recited in claim 9, wherein said at least one sensor comprises a DC type sensor, said method further comprising sensing, with said DC type sensor, a static or slowly varying magnetic field established by said permanently magnetized threat object.

11. The method recited in claim 10, further comprising:
providing at least one said DC type sensor on a first vertical member of said frame on a first side of said opening; and
providing at least one said DC type sensor on a second vertical member of said frame on a second side of said opening.

12. The method recited in claim 10, further comprising providing at least one said DC type sensor on a horizontal member of said frame above said opening.

13. The method recited in claim 9, wherein said at least one sensor comprises a large induction coil, said method further comprising sensing, with said large induction coil, a slowly varying magnetic field established by movement of said permanently magnetized threat object through said opening of said frame.

14. The method recited in claim 9, further comprising:
providing a first vertical array of said AC induction coils on a first vertical member of said frame on a first side of said opening; and
providing a second vertical array of said AC induction coils on a second vertical member of said frame on a second side of said opening.

15. The method recited in claim 14, further comprising:
providing a first said applied field coil adjacent to said first vertical member of said frame;
providing a second said applied field coil adjacent to said second vertical member of said frame; and
extending horizontal axes of said first and second applied field coils across said opening of said frame.

16. The method recited in claim 9, further comprising providing a horizontal array of said AC induction coils on a horizontal member of said frame above said opening.
